(19) United States
(12) Patent Application Publication
(10) Pub. No.: US 2026/0147377 A1
(43) Pub. Date: May 28, 2026

(54) ADJUSTABLE HEIGHT VIDEO DISPLAY

(71) Applicant: Vizio, Inc., Irvine, CA (US)

(72) Inventors: Glen Gihong Kim, Anaheim, CA (US); Aung Khin Soe Win, Anaheim, CA (US); Kasin Chan, Chino, CA (US)

(21) Appl. No.: 19/352,634

(22) Filed: Oct. 8, 2025

Related U.S. Application Data
(60) Provisional application No. 63/705,233, filed on Oct. 9, 2024.

(51) Int. Cl. G06F 1/16; H05K 5/02

(52) U.S. Cl. CPC G06F 1/1601; H05K 5/0234; G06F 2200/1612

(57) ABSTRACT

A dual height video display is provided and is adjustable between two configurations that define two distances between a bottom surface of the display and a support surface (e.g., table top) upon which the display rests. Support members are provided which are attachable to a bottom surface of the display in two different orientations that space the video display bottom surface from the support surface by different distances without varying a degree of insertion of the support members into the video display housing. The point of attachment on the video display for attaching the support members is the same in both configurations. The support member includes two video display engagement surfaces with fastener openings, which are oriented perpendicularly to one another.

### CROSS-REFERENCE TO RELATED APPLICATIONS

This application claims the benefit of U.S. Provisional Patent Application No. 63/705,233, filed Oct. 9, 2024, the entirety of which is hereby incorporated by reference.

### FIELD

The present disclosure relates to video displays such as TVs, home theater displays, and computer monitors with detachable support members that allow the display to be spaced apart from a support surface such as a desk or tabletop by an adjustable distance.

### BACKGROUND

In known adjustable height video displays, the support members are attached at different locations along the height of the display (or vice-versa) to space the bottom of the display at different distances from the desk or tabletop that the display rests on. Such designs require more complex attachment mechanisms on the support members or on the display itself, such as internal housing structures that allow support members to be inserted to varying degrees of insertion. Thus, a need has developed for an adjustable height video display that reduces the complexity of such known designs.

### BRIEF DESCRIPTION OF THE DRAWINGS

FIGS. 1A-1C depict a prior art adjustable height video display assembly;

FIG. 2A is a front elevational view of a video display assembly in an extended height configuration in accordance with a first embodiment of the present disclosure;

FIG. 2B is a front elevational view of the video display assembly of FIG. 2A in a reduced height configuration;

FIG. 3A is a close-up of the video display assembly of FIG. 2A showing the right support member in the extended height configuration;

FIG. 3B is a close-up view of the video display assembly of FIG. 2A showing the right support member in the reduced height configuration;

FIG. 4A is an exploded close-up perspective view of the left-side of the video display assembly of FIG. 2A showing the left support member prior to attachment to the bottom of the video display in the extended height configuration;

FIG. 4B is a close-up front elevational view of the left-side of the video display assembly of FIG. 2A in the extended height configuration;

FIG. 4C is an exploded close-up view of the left-side of the video display assembly of FIG. 2A showing the left support member prior to attachment to the bottom of the video display in the reduced height configuration;

FIG. 4D is a close-up front elevational view of the left-side of the video display assembly of FIG. 2A in the reduced height configuration;

FIG. 5A is a close-up exploded view of the left support member and the video display of the video display assembly of FIG. 2A prior to the attachment of the left support member in the extended height configuration;

FIG. 5B is a close-up exploded view of the left support member and the video display of the video display assembly of FIG. 2A prior to the attachment of the left support member in the reduced height configuration;

FIG. 6A is a close-up exploded view of a video display assembly in accordance with a second embodiment of the present disclosure showing the left support member prior to attachment to the video display in a reduced height configuration;

FIG. 6B is a close-up view of the video display assembly of FIG. 6A showing the left support member attached to the video display in a reduced height configuration;

FIG. 6C is a close-up view of the lower bottom surface of the video display assembly of FIG. 6A;

FIG. 6D is a close-up view of the lower left-hand portion of the video display of FIG. 6A showing the internal engagement of the left support member with a video display support engagement surface recessed in a bottom surface of the video display;

FIG. 6E is a partial perspective view of the lower left hand portion of the video display assembly of FIG. 6A, showing the left support member in an installed condition and a reduced height configuration;

FIG. 7A is a close-up, exploded view of the lower left hand portion of the video display assembly of FIG. 6A showing the left support member prior to attachment to the video display assembly in an extended height configuration;

FIG. 7B is a close-up, lower perspective view of a lower left-hand portion of the video display of FIG. 6A showing the left support member in an installed condition and an extended height configuration;

FIG. 7C is a close-up view of the lower-left hand portion of the video display assembly of FIG. 6A showing the internal engagement of the left support with a video display support engagement surface recessed in a bottom surface of the video display; and

FIG. 7D is a close-up view of the lower-left hand portion of the video display assembly of FIG. 6A showing the left support member in an installed condition and an extended height configuration.

### DETAILED DESCRIPTION

The disclosed video display assemblies comprise two separate support members that support a video display on a support surface such as a desk, tabletop, shelf, etc. Each of the support members is structured to attach to the video display to space the display at two different distances from the support surface. The two different distances define a reduced height configuration and an extended height configuration. The extended height configuration provides additional space between the lower surface of the video display and the support surface its sits on and can accommodate accessories like soundbars beneath the display. In preferred examples, the support members attach to the same video display support engagement surface on the video display in both a reduced height and extended height configuration. However, the orientation of the support members differs in the reduced height and extended height configurations.

The support members comprise first and second legs and are preferably integrally formed into single, one piece components. Rubber grips may be added to one of the legs of each support member to provide enhanced frictional engagement between the support members and the support surfaces on which they rest and to prevent scratching of the support surface by the support member legs.

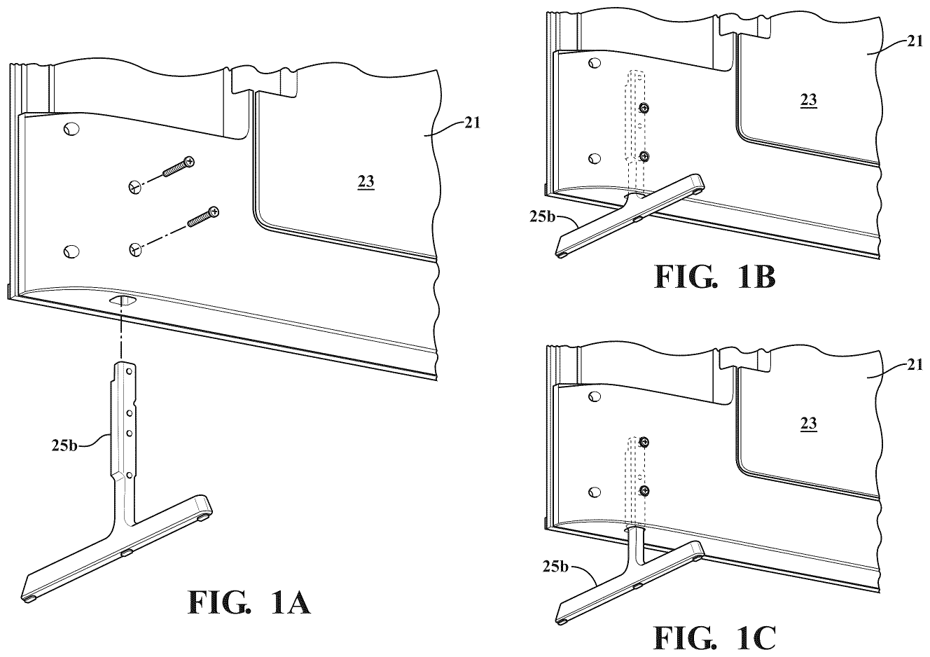

FIGS. 1A-1C depict a prior art video display assembly 21 comprising a display 23 and support members 25a (not shown), and 25b. The support members 25a, 25b have a fixed height and are inserted vertically within the housing of display 23 to different degrees depending on whether the video display assembly 21 is in a reduced height (FIG. 1B) or extended height (FIG. 1C) configuration. The orientation of the support members 25a, 25b does not change between the two embodiments. Rather the degree to which the support members are inserted in the display 23 housing is.

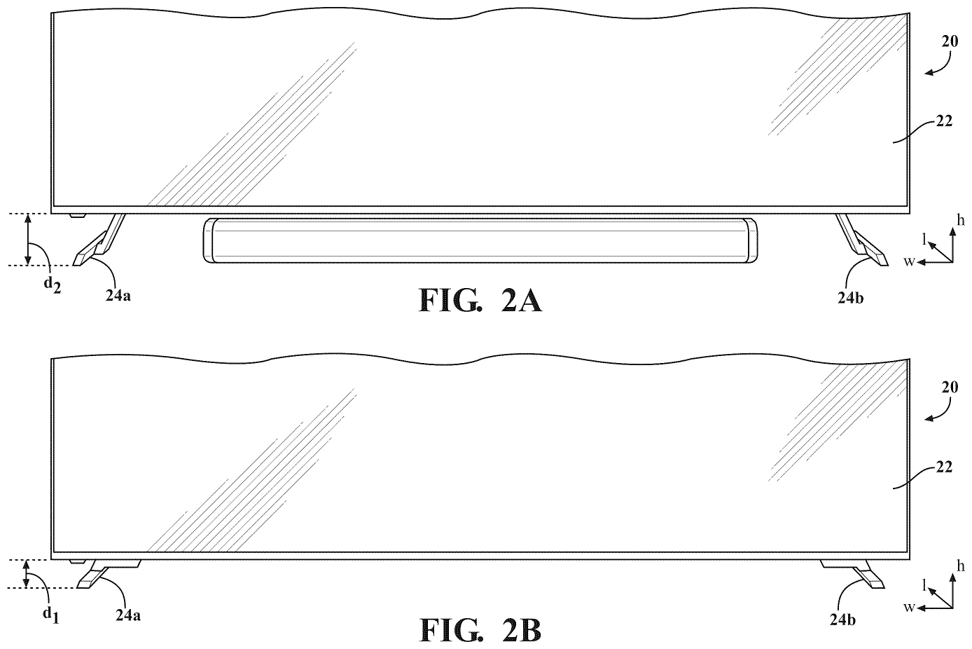

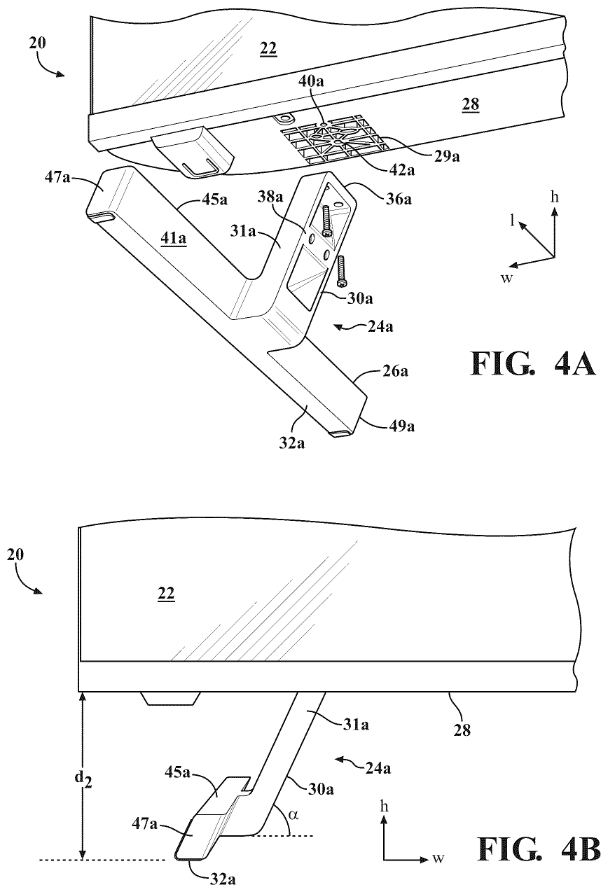

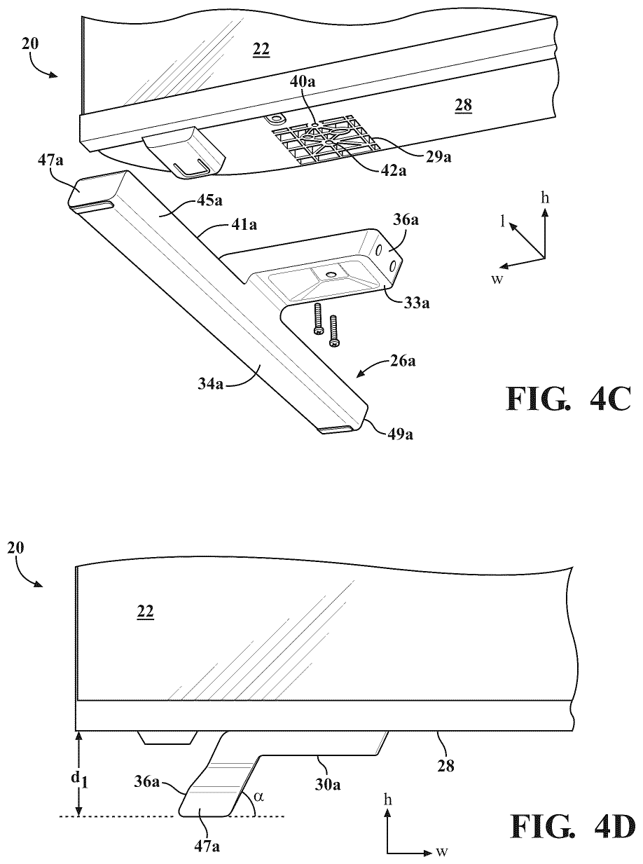

Referring to FIGS. 2A-5B, a first example of a video display assembly 20 in accordance with the present disclosure is shown. Video display assembly 20 comprises a video display 22 and right and left support members, 24a and 24b, respectively, which are spaced apart from one another along the video display 22 width axis. FIGS. 2A, 3A, 4A-B and 5A depict assembly 20 in an extended height configuration. FIGS. 2B, 3B, 4C-4D, and 5B depict video display assembly 20 in a reduced height configuration. In the extended height configuration, a vertical distance d1 (FIG. 4B) along the height (h) axis is defined between the lower surface 28 of video display 22 and a support surface. The spacing d1 is greater than a vertical distance d2 (FIG. 4D) defined between the lower surface 28 of video display 22 and a support surface in the reduced height configuration. It should be understood that support members 24a and 24b are identical to one another and are installed in a mirror image orientation relative to one another in each of the reduced height and extended height configurations, respectively. Thus, where one or the other of support members 24a, 24b is described, it should be understood that the other has the same structure and operation.

In both the reduced and extended height orientations, support members 24a and 24b preferably attach to the same video display support engagement surface 29a, 29b which is located on the lower surface 28 of video display 22. However, the support members 24a and 24b each have respective extended height video display engagement surfaces, 36a, 36b and respective reduced height video display engagement surfaces 38a, 38b to configure the video display assembly in the desired extended height or reduced height configuration. Further, support members 24a and 24b have different support surface engagement surfaces 32a/32b (extended height configuration) and 34a/34b (reduced height configuration) which engage a support surface (e.g., desk top, tabletop, or shelf). The extended height spacing d1 between lower surface 28 of video display 22 and the support surface on which it rests is defined by the distance between the video display engagement surface 36a/36b and support surface engagement surface 32a/32b.

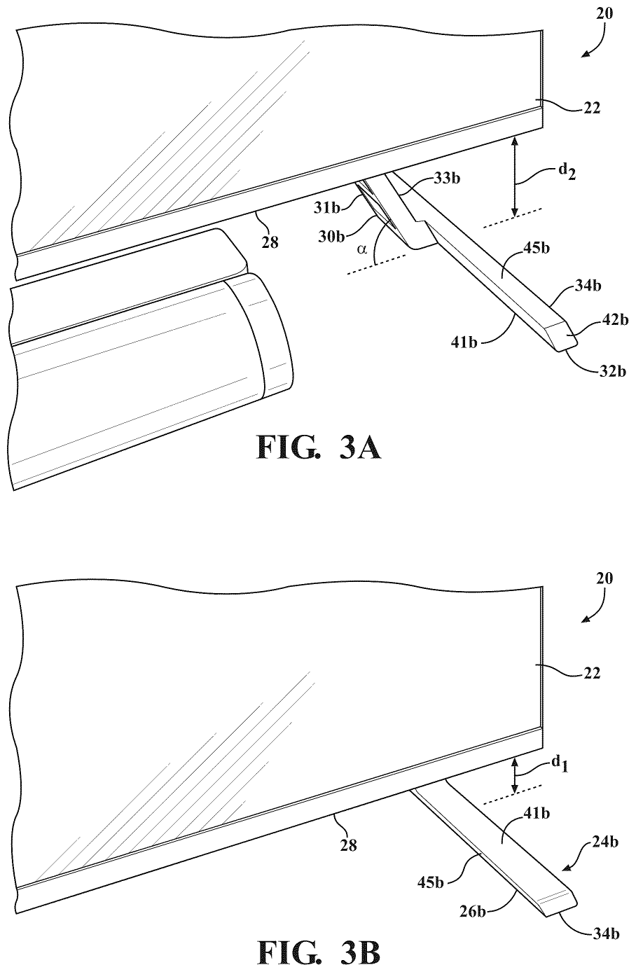

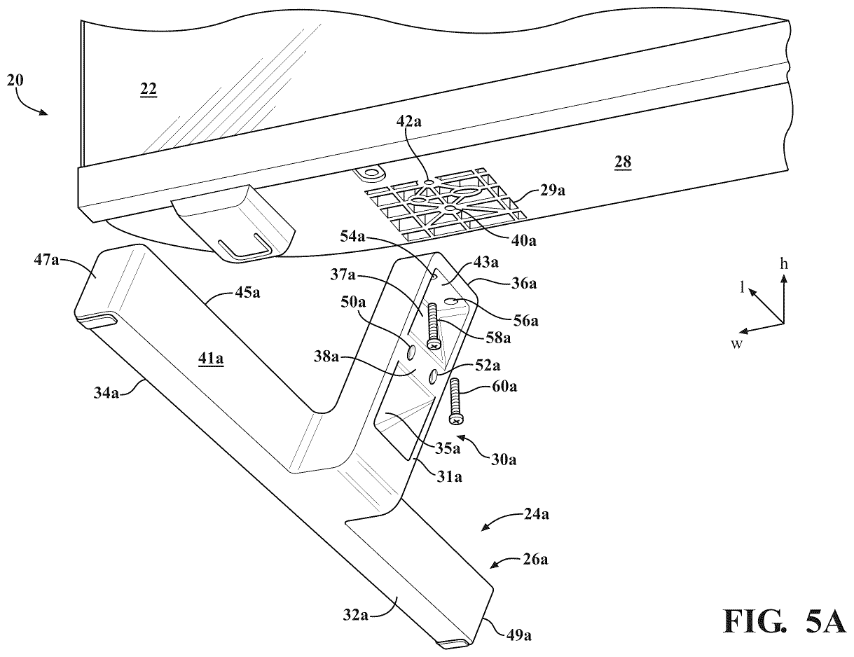

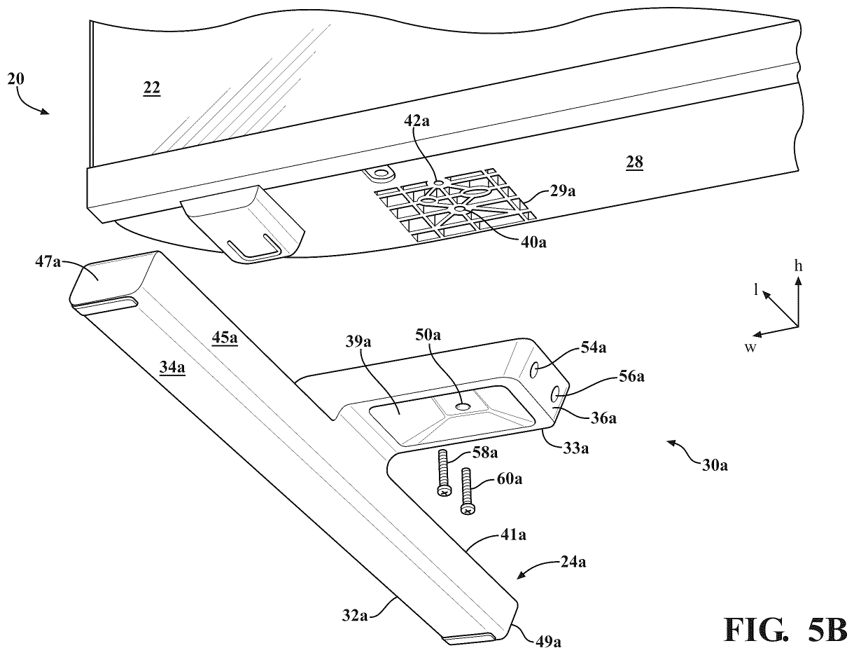

Referring to FIGS. 2A, 3A, 4A-B, and 5A, the extended height configuration of video display assembly 20 will now be described. Referring to the extended height configuration, support members 24a and 24b attach to respective video display support engagement surfaces 29a, 29b on a bottom surface 28 (FIGS. 3A-B) of video display 22. The video display support engagement surfaces 29a and 29b comprise fastener openings 40a, 42a (FIG. 5A) which are spaced apart from one another along the video display length (l) axis. Support members 24a, 24b are spaced apart from one another along a width(w) axis of the video display 22. In FIGS. 2A, 3A, 4A-B, and 5A, support members 24a and 24b are each attached to the video display bottom surface 28 in a first orientation that defines an extended height configuration with a vertical spacing d1 (FIG. 4B) between the bottom video display surface 28 and a support surface on which the support members 24a and 24b rest, such as a desk, tabletop, or shelf.

Left hand support member 24a has a first leg 26a which has first and second ends 47a and 49a which are parallel to one another and spaced apart along the length axis of support member 24a, which is parallel to the length axis (l) of video display assembly 20 when support member 24a is in an installed condition on lower surface 28.

In the extended height configuration first video display engagement surface 36a of support member 24a abuttingly engages video display support engagement surface 29a formed in bottom surface 28 of video display 22. Second leg 30a extends from second leg attachment surface 41a and projects away from second leg 30a along the video display height axis and slightly inward toward the video display assembly 20 width axis mid-line along the video display width axis (w) when support member 24a is in an installed condition.

Surface 34a is located opposite second leg attachment surface 41a. In the installed condition and extended height configuration, the support surface engagement surface of support leg 26a is surface 32a. Surface 32a is opposite surface 45a which is an upward facing surface of support leg 26a when support member 24a is in an installed condition on support member 24a.

Second leg 30a of support member 24a has a first side 31a (FIG. 5A) and a second side 33a (FIG. 5B) spaced apart from one another along a thickness axis of second leg 30a (which is the width axis of video display assembly 20 when it is in an extended height configuration). Second video display engagement surface 38a is located between two recesses 35a and 37a along a length axis of the second leg 30a (and along the height axis of video display assembly 20).

Second recess 37a defines an inner surface 43a that is opposite first video display engagement surface 36a and spaced apart from first video display engagement surface 36a when video display assembly 20 is in an extended height configuration. Through holes 54a and 56a (FIG. 5B) extend from inner surface 43a to first video display engagement surface 36a. In an installed, extended height configuration, through holes 54a and 56a align with respective openings 42a and 40a in the video display support engagement surface 29a formed in bottom surface 28 of video display 22. Fastener (e.g., screw or bolt) 58a extends through hole 54a and into video display bottom surface opening 42a, and fastener 60a extends through hole 56a and into video display bottom surface opening 40a to fasten the support member 24a to the bottom surface 28 in the extended height configuration. In the extended height configuration, first support surface engagement surface 32a of first leg 26a rests on a support surface.

In FIGS. 2B, 3B, 4C-4D and 5B, support members 24a and 24b are attached to bottom video display support engagement surfaces 29a, 29b, respectively, in a second orientation that defines a reduced height configuration. Support members 24a and 24b are identical and like components or sections have like numbers and are distinguished with an “a” or “b” subscript.

In FIGS. 2B, 3B, 4C-D, and 5B, support members 24a and 24b are attached to bottom video display surface 28 in a second orientation that defines a reduced height configuration in which the video display bottom surface 28 is spaced apart from the support surface on which the support members 24a and 24b rest by a second distance d1, wherein d1 of FIGS. 2B and 3B is less than d2 of FIGS. 2A and 3A.

As indicated above, different surfaces of first support member 24a act as support surface engagement surfaces that rest on a surface beneath video display 22 depending on whether video display assembly 20 is in an extended or reduced height configuration. First leg 26a has a first support surface engagement surface 32a and a second support surface engagement surface 34a. First support surface engagement surface 32a and opposing surface 45a are spaced apart along an axis perpendicular to first support surface engagement surface 32a and opposing surface 45a. Second support surface engagement surface 34a and opposing surface 41a are spaced apart along an axis perpendicular to second support surface engagement surface 34a and opposing surface 41a. First video display engagement surface 36a is substantially parallel to first support surface engagement surface 32a, and second video display engagement surface 38a is substantially parallel to second support surface engagement surface 34a. The first video display engagement surface 36a of second leg 30a is spaced apart from the first support surface engagement surface 32a by a distance that is greater than a distance by which second video display engagement surface 38a is spaced apart from second support surface engagement surface 34a. The two different spacings between the respective pairs of video display engagement surfaces 36a, 38a and the corresponding support surface engagement surfaces 32a, 34a to which they are respectively parallel define the spacing distance differential d1-d2 between the extended and reduced height configurations.

The reduced height configuration distance d1 between the lower surface 28 of video display assembly 20 and a support surface on which support members 24a and 24b rest is defined by the distance between video display engagement surface 38a and support surface engagement surface 34a along an axis perpendicular to support surface engagement surface 34a. The extended height configuration distance d2 between the lower surface 28 of video display assembly 20 and the support surface on which support members 24a and 24b rests is defined by the distance between video display engagement surface 36a and support surface engagement surface 32a.

First video display engagement surface 36a lies in a plane that is perpendicular to a plane in which second video display engagement surface 38a lies, and first support surface engagement surface 32a lies in a plane that is perpendicular to a plane in which second support surface engagement surface 34a lies. Each support surface engagement surface 32a and 34a may have a pair of rubber grips to provide enhanced friction between the respective support surface engagement surface 32a and 34a and a support surface on which the support surface engagement surfaces (e.g., desk or tabletop) 32a and 34a rest.

Referring to FIG. 5B, in an installed, reduced height configuration, second side 33a of second leg 30a has a recess 39a that defines a bottom surface opposite second video display engagement surface 38a and through which through holes 50a and 52a extend. Through holes 50a and 52a have lengths that are substantially perpendicular to lengths of through holes 54a and 56a. In the reduced height configuration, second video display engagement surface 38a of second leg 30a abuttingly engages video display support engagement surface 29a of bottom surface 28 of video display 22. Through holes 50a and 52a extend from side 31a to side 33a of second leg 30a. Fastener 58a extends through throughhole 52a and video display bottom surface opening 42a, and fastener 60a extends through throughhole 50a and video display bottom surface opening 40a in the reduced height configuration or the extended height configuration.

In certain examples, the length of second support leg 30a defines an axis that intersects a plane defined by first support surface engagement surface 32a and the support surface itself at an angle α (FIG. 4B). with the same angle α being defined between the length of support member 30b and first support surface engagement surface 32b and between the length of support member 30b and the support surface itself. In both the extended and reduced height configurations, the angle α is preferably greater than 30 degrees, more preferably greater than 40 degrees and still more preferably greater than 45 degrees.

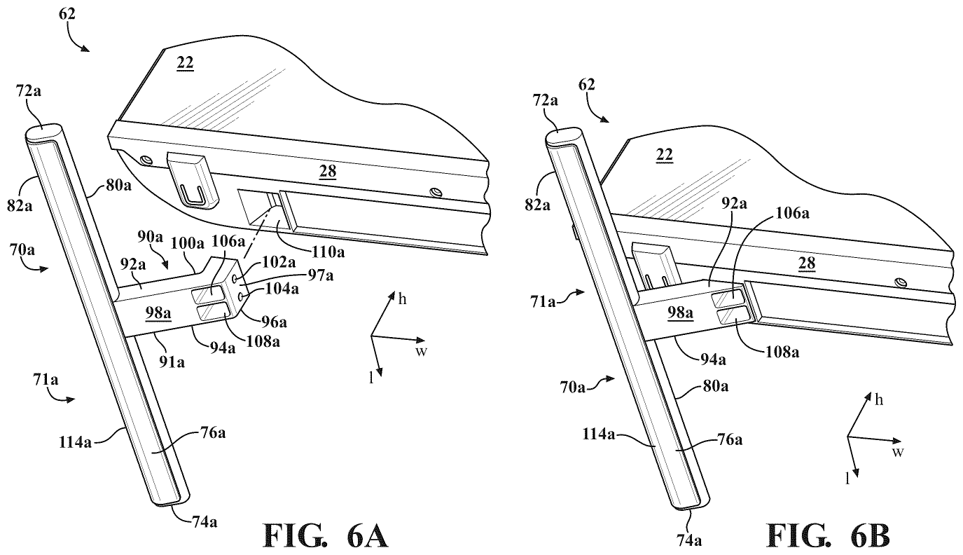

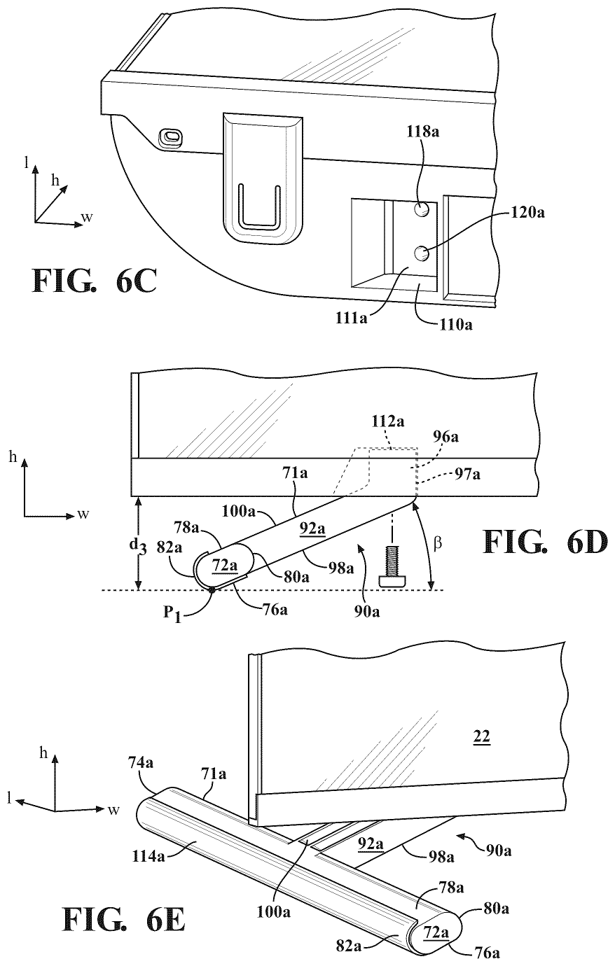

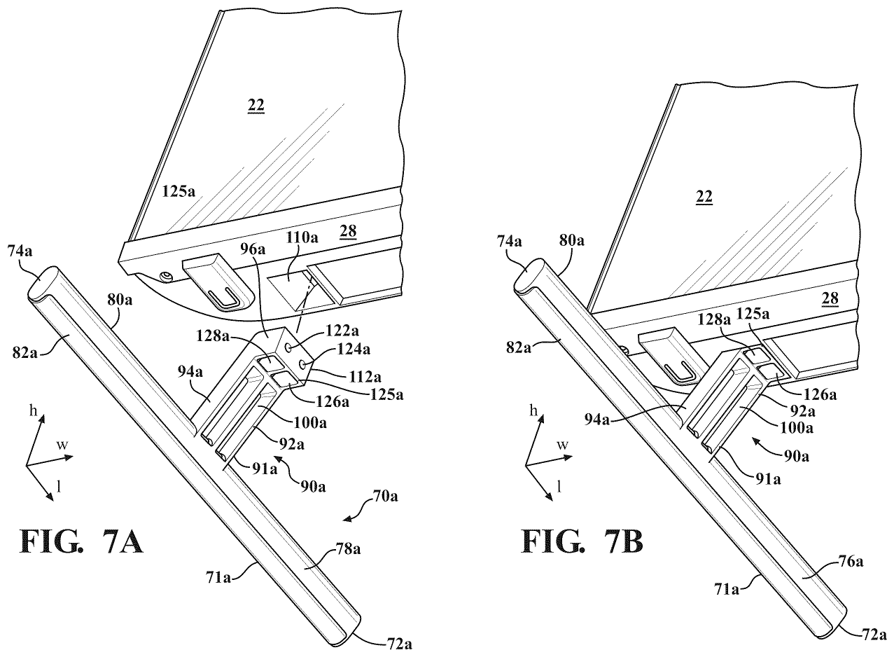

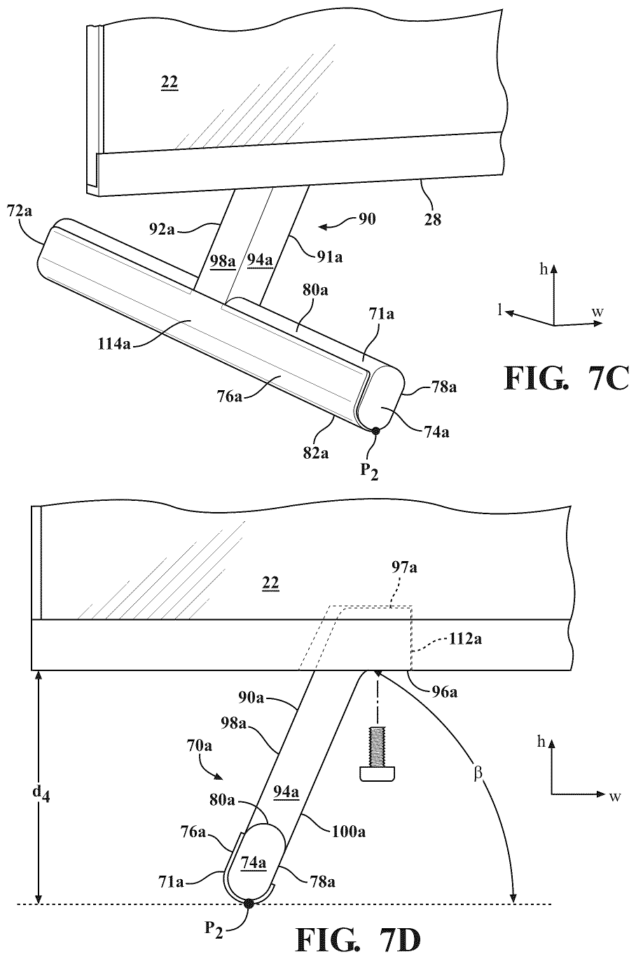

Referring to FIGS. 6A-6E and FIGS. 7A-7D, a second example of a video display assembly 62 is provided. Video display assembly 62 comprises video display 22 and two support members 70a and 70b (not shown). It is understood that support member 70b has the same structure and functions in the same manner as support member 70a and that the two support members 70a and 70b are essentially mirror images of one another when installed on video display 22. FIGS. 6A-6E show video display assembly 62 is installed in a reduced height configuration in which bottom surface 28 of video display 22 is spaced apart from a support surface on which video display assembly 62 rests by a distance d3, and FIGS. 7A-7E show video display assembly 62 in an extended height configuration in which video display 22 display bottom surface 28 is spaced apart from a support surface on which video display assembly 20 rests by a distance d4, wherein d4 is greater than d3.

Referring to FIGS. 6A-6E, support member 70a comprises a first leg 71a which has a first end 72a and a second end 74a spaced apart from one another along a support member length (l) axis. Support member 70a also comprises a second leg 90a. Second leg 90a includes a linear section 91a and a projection 96a so that second leg 90a has an “L-shape.” Linear section 91a projects away from first leg 71a in a direction that is perpendicular to the length axis and along the width and height axes. Linear section 91a has a first surface 98a and second surface 100a which are spaced apart from one another along the height (h) axis with the second surface 100a being vertically higher than first surface 98a when video display assembly 62 is in a reduced height configuration. Linear section 91a of second leg 90a also includes a first side surface 92a and second side surface 94a which are spaced apart from one another along the length (l) axis with first side surface 92a being closer to the screen of the video display 22 (and hence, the viewer). Vertical projection 96a is generally cubic in shape and includes an upward facing surface 112a (FIG. 7A) that includes two fastener holes 122a, 124a. Thus, in the reduced height configuration, upward facing surface 112a is a video display engagement surface. Fastener holes 122a, 124a are in communication with recesses 106a and 108 formed in first surface 98a (FIG. 6A) of second leg linear section 91a. Although referred to as a “vertical” projection in the context of FIG. 6A-6E, in the extended height configuration, projection 96a projects horizontally, along the width axis direction, relative to linear section 91a of second leg 90a.

Vertical projection 96a is configured to fit within a recess 110a formed in the lower surface 28 of display 22 (FIG. 6D). Fasteners can be inserted vertically upward in recesses 106a and 108a. The fasteners are received by openings 118a, 120a in upper surface 111a of video display recess 110a (FIG. 6C) to secure support member 70a to video display 22. In the example of FIGS. 6A-E and 7A-D, upper surface 111 a of video display recess 110a acts as video display engagement surface in both the extended height and reduced height assemblies.

First leg 71a comprises two generally planar opposing surfaces 76a and 78a, each of which extends along the length (l) axis, and two opposing curved surfaces 80a and 82a, which also extend along the length (l) axis. In the reduced height configuration of FIGS. 6A-6E, planar surface 76a is angled downward, and planar surface 78a faces upward. Curved surface 80a is angled upward and is located inward of curved surface 82a along the width (w) axis of display 22. A rubber grip 114a extends around curved surface 82a to provide a source of frictional resistance when first leg 71a is resting on a support surface (FIG. 6D). In the reduced height configuration of FIGS. 6A-6E, a portion of lower curved surface 82a acts as a support surface engagement surface which rests on the support surface and defines a linear strip (extending along the video display 22 length axis) that engages the support surface. The point P1 in FIG. 6D reflects this location of engagement between the curved surface 82a and the support surface. Although P1 appears as a point of tangency, it is understood that it will have some width along the width axis and that it extends along the length axis.

In the reduced height configuration of FIGS. 6A-6E, the lower surface 98a of linear section 91a and the support surface define a support incline angle β. The angle β preferably ranges from about 30°to about 60°, more preferably from about 35°to about 55°, and more preferably from about 40°to about 50°.

Referring to FIGS. 7A-7D the video display assembly 62 of FIGS. 6A-6E is shown in an extended height configuration. Relative to the reduced height configuration of FIGS. 6A-6E, support member 70 a is rotated about width axis (w) 180 degrees and is then rotated 90 degrees about the length (l) axis so support member 72 a is reoriented as shown in FIGS. 7A-7E. This reorientation alters the angle β between the bottom surface 28 of video display 22 and the support surface on which the video display assembly 62 rests. In the extended height configuration of FIGS. 7A-7E, the elevation angle β (FIG. 7B) ranges from about 60°to about 90°, preferably from about 65°to about 85°and more preferably from about 70°to about 80°.

Curved surface 82a of first leg 71a is the surface that engages a horizontal support surface in both the reduced and extended height configurations. However, as shown in FIGS. 6D and 7D the point of tangency P2 in the extended height configuration is farther from planar side 78a in the extended height configuration relative to the reduced height configuration. Again, P2 is not actually a point of tangency, but rather has some thickness along the width (w) axis and extends along the length axis.

In the extended height configuration of FIGS. 7A-7D, the positions of the various surfaces of support members 70a and 70b change relative to the reduced height configuration. First leg planar surface 78a is inward (along the width (w) axis) of opposing first leg planar surface 76a in the extended height configuration relative to the reduced height configuration. Second leg 90a linear section side surface 94a is forward (closer to the screen of display 22 along the length (l) axis) of linear section side surface 92a in the extended height configuration but is rearward of it in the reduced height configuration. The upward facing surface 112a of vertical projection 96a in FIG. 6D faces inwardly along the width axis (toward the longitudinal midline of display 22) in the extended height configuration and its orientation is perpendicular to the width (w) axis, whereas it is vertically upward facing and perpendicular to the height axis the reduced height configuration.

In the example of FIGS. 6A-E and 7A-D, support members 70a and 70b each include two different video display engagement surfaces. With respect to support member 70a, each of the two video display engagement surfaces 97a, 112a respectively engages the same video display support engagement surface 111a on the video display 22 to place the video display assembly 62 in either a reduced height configuration or an extended height configuration. In certain examples, the two video display engagement surfaces 97a and 112a are adjacent one another. In the same or other examples, video display engagement surfaces 97a and 112a are perpendicular to one another. In the same or other examples, both video display engagement surfaces 97a, 112a are spaced apart from a support surface engagement surface 82a of support member 70a along an axis defined by the length of second leg 90a. 70b is understood to b configured the same way, but its corresponding components bear the “b” suffix.

Surface 112a serves as a video display 22 engagement surface when connecting support member 70a in a reduced height configuration. Surface 112a abuttingly engages surface 111a that defines recess 110a in the bottom surface 28 of video display 22 in the reduced height configuration. Correspondingly, surface 97a of projection 96a serves as the video display engagement surface in the extended height configuration. Projection surface 97a includes fastener openings 102a, 104a (FIG. 6A). Openings 102a, 104a are aligned with a respective one of openings 118a and 120a in the display recess 110a. The openings 102a and 104a provided in projection surface 97a are in communication with recesses 126a and 128a formed in side 125 of projection 96a. As shown in FIG. Side 125 is opposite projection surface 97a and is adjacent surface 100a of second leg 90a.

In the video display assemblies 20 and 62, the height of the display 22 from a support surface (d3, d4) is adjusted without adjusting a degree of insertion of a support member into the display housing. Instead, the distance between the support members'support surface engagement surface 82a, 82b and a fixed location video display support engagement surface 111a, 111b, respectively, is adjusted, which in turn adjusts the angle of inclination between the linear section 91a and the support surface, and consequently, the distance from the bottom surface 28 of video display 22 and the support surface.

Video display assemblies 20 and 62 provide a means of using identical support hardware to put a video display 22 in either a reduced or extended height configuration relative to a support surface in which the video display 22 sits. In the example of FIGS. 2A-6B, support members 24a, 24b and fasteners 58a, 60a, 58b (not shown) and 60b (not shown) are sufficient to support the display 22 reliably in either a reduced or extended height configuration. In the example of FIGS. 6A-7D, support members 70a, 70b and four fasteners (two per support member) are sufficient to reliably support the display 22 in either an extended height or reduced height configuration.

What is claimed is:

1. A video display support member, comprising: a first leg with at least one support surface engagement surface and a second leg with first and second video display engagement surfaces, wherein the first and second video display engagement surfaces are oriented at about ninety degrees with respect to one another.

2. The video display support member of claim 1, wherein the at least one support surface engagement surface comprises first and second support surface engagement surfaces.

3. The video display support member of claim 1, wherein the second leg has a length defining a length axis, a width defining a width axis, and a thickness defining a thickness axis, a first side spaced apart from a second side along the thickness axis, at least one throughhole extending from the first side to the second side along the thickness axis, and the first side includes the first video display engagement surface.

4. The video display support member of claim 3, the second leg further comprising a first recess spaced apart from a second recess along the length axis, such that the first video display engagement surface is located between the first recess and the second recess along the length axis.

5. The video display support member of claim 4, wherein the first recess defines an interior surface opposing the first video display engagement surface, the second leg further comprising at least one throughhole from the interior surface to the second video display engagement surface.

6. The video display support member of claim 1, wherein the first leg has a first length defining a first leg length axis, the second leg has a second length defining a second length axis, and the first length axis is perpendicular to the second length axis.

7. The video display support member of claim 1, wherein the second leg's first video display engagement surface is spaced apart from the first leg along a first axis and a second axis, and the second leg's second video display engagement surface is spaced apart from the first leg along the first axis and the second axis.

8. The video display support member of claim 1, wherein the at least one support surface engagement surface comprises first and second support surface engagement surfaces, the first video display engagement surface has a first at least one throughhole, the second video display engagement surface has a second at least one throughhole, the first at least one through hole has a length, the second at least one throughhole has a length, and the first at least one throughhole length is perpendicular to the second at least one through hole length.

9. The video display support member of claim 8, wherein the first at least one throughhole length is perpendicular to the first support surface engagement surface of the first leg, and the second at least one throughhole length is perpendicular to the second support surface engagement surface of the first leg.

10. The video display support member of claim 8, wherein the second leg has a length defining a second length axis, and the first at least one throughhole is spaced apart from the second at least one throughhole along the second length axis.

11. The video display support member of claim 1, wherein the at least one support surface engagement surface comprises first and second support surface engagement surfaces, the first video display engagement surface is parallel to the second support surface engagement surface and the second video display engagement surface is parallel to the first support surface engagement surface.

12. A video display assembly, comprising:
a video display having a bottom surface; and
at least one video display support member comprising first and second video display engagement surfaces and first and second support surface engagement surfaces for contacting a support object;
wherein the first video display engagement surface is parallel to the second support surface engagement surface, the second video display engagement surface is parallel to the firs support surface engagement surface, when the first video display engagement surface engages the video display bottom surface, the second support surface engagement surface is spaced apart from the video display bottom surface by a first distance, when the second video display engagement surface engages the video display bottom surface, the first support surface engagement surface is spaced apart from the video display bottom surface by a second distance, and the second distance is greater than the first distance.

13. A video display assembly, comprising:
a video display having a bottom surface; and
at least one video display support member having first and second support surface engagement surfaces;
wherein in a first configuration the video display support member is attached to the video display bottom surface such that the first support surface engagement surface is parallel to the video display bottom surface, and in a second configuration the video display support member is attached to the video display bottom surface such that the second support surface engagement surface is parallel to the video display bottom surface.

14. The video display assembly of claim 13, wherein in the first configuration, the first support surface engagement surface is spaced apart from the video display bottom surface by a first distance, the second video display engagement surface is spaced apart from the video display bottom surface by a second distance, and the first distance is greater than the second distance.

15. The video display assembly of claim 14, wherein in the first configuration and the second configuration, the at least one video display support member is beneath the video display bottom surface.

16. A video display assembly, comprising:
a video display having a video display support engagement surface;
first and second support members, wherein each support member has a support surface engagement surface, a reduced height display engagement surface, and an extended height display engagement surface, wherein when the first support member is attached to the video display by attaching the reduced height display engagement surface of the first support member to the video display support engagement surface, a first distance is defined between the video display support engagement surface and the first support member support surface engagement surface along a video display height axis, and a second distance is defined between the video display support engagement surface and the first support member support surface engagement surface along a video display width axis, and when the first support member is attached to the video display by attaching the extended height display engagement surface of the first support member to the video display support engagement surface, a third distance is defined between the video display support engagement surface and the first support member support surface engagement surface along the video display height axis, a fourth distance is defined between the video display support engagement surface and the first support member support surface engagement surface along the video display width axis, the third distance is greater than the first distance, and the fourth distance is less than the second distance.

17. The video display assembly of claim 16, wherein the video display support engagement surface comprises a first video display support engagement surface, and the video display assembly comprises a second video display support engagement surface spaced apart from the first video display support engagement surface along the video display width axis, and when the second support member is attached to the video display by attaching the reduced height display engagement surface of the second support member to the second video display support engagement surface, the second video display support engagement surface and the second support member support surface engagement surface are spaced apart along the video display height axis by the first distance.

18. The video display assembly of claim 17, wherein when the second support member is attached to the video display by attaching the extended height display engagement surface of the second support member to the second video display support engagement surface, the second video display support engagement surface and the second support member support surface engagement surface are spaced apart along the video display height axis by the third distance.

19. The video display assembly of claim 16, wherein the first support member comprises:
a first leg having a length defining a length axis;
a second leg having a linear section and a projection, wherein the linear section projects away from the first leg in a direction perpendicular to the first leg, and the projection comprises the first support member reduced height display engagement surface and the first support member extended height engagement surface.

20. The video display assembly of claim 19, wherein the first support member reduced height display engagement surface is perpendicular to the first support member extended height display engagement surface.
